(19) United States
(12) Patent Application Publication
(10) Pub. No.: US 2026/0057132 A1
(43) Pub. Date: Feb. 26, 2026

(54) SHOCK ABSORBING SOLID STATE BATTERY

(71) Applicant: INTERNATIONAL BUSINESS MACHINES CORPORATION, Armonk, NY (US)

(72) Inventors: Sarbajit Kumar Rakshit, Kolkata (IN); Logan Bailey, Atlanta, GA (US); Zachary Augustus Silverstein, Georgetown, TX (US)

(21) Appl. No.: 18/815,041

(22) Filed: Aug. 26, 2024

(51) Int. Cl. G06F 30/17; H01M 50/14

(52) U.S. Cl. CPC G06F 30/17; H01M 50/14

(57) ABSTRACT

A computer-implemented method for battery design includes determining operational shock and vibration imparted to a solid-state battery and determining portions of the solid-state battery susceptible to damage. Countermeasures are selected for the portions by identifying shock and vibration elements and positions for the shock and vibration elements in the solid-state battery. A three-dimensional (3D) design for a new solid-state battery including the countermeasures is generated. The new solid-state battery is fabricated according to the 3D design using an additive manufacturing process.

### BACKGROUND

The present invention generally relates to solid state batteries and, more particularly, to batteries with shock absorbing mechanisms to prevent cracking.

A lithium-ion battery is composed of a cathode, anode, separator and electrolyte. A lithium-ion battery for smartphones, power tools and electric vehicles (EVs) employs liquid electrolyte batteries. A solid-state battery uses a solid electrolyte, not liquid/gel. Solid-state batteries have greater energy storage density, have increased reliability and wear resistance, and are faster charging.

At high temperatures, liquid electrolytes can become volatile and flammable. While solid electrolytes have improved thermal stability, which limits the risk of fire or explosion, impact or mechanical stress can cause damage to a solid-state battery electrolyte cell. Applied impact shocks on a battery can result in dendrite formation and with additional shock or stress cracking can occur. Cracks can lead to significant loss of efficiency up to catastrophic battery failure.

### SUMMARY

In accordance with an embodiment of the present invention, a computer-implemented method for battery design includes determining operational shock and vibration imparted to a solid-state battery and determining portions of the solid-state battery susceptible to damage. Countermeasures are selected for the portions by identifying shock and vibration elements and positions for the shock and vibration elements in the solid-state battery. A three-dimensional (3D) design for a new solid-state battery including the countermeasures is generated. The new solid-state battery is fabricated according to the 3D design using an additive manufacturing process.

In accordance with another embodiment of the present invention, a system for battery design includes a hardware processor and a memory that stores a computer program which, when executed by the hardware processor, causes the hardware processor to determine operational shock and vibration imparted to a solid-state battery, determine portions of the solid-state battery susceptible to damage, select countermeasures for the portions by identifying shock and vibration elements and positions for the shock and vibration elements in the solid-state battery and generate a three-dimensional (3D) design for a new solid-state battery including the countermeasures. The new solid-state battery is fabricated according to the 3D design using an additive manufacturing process.

In accordance with another embodiment of the present invention, a solid-state battery includes components having an anode, a cathode and a solid-state electrolyte disposed between the anode and the cathode. A countermeasure is integrally incorporated within at least one of the components to absorb mechanical energy to prevent physical damage to the components.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a block diagram of a system for designing a solid-state battery having shock and vibration absorbing features integrated therein, in accordance with an embodiment of the present invention;

FIG. 2 is a schematic cross-section diagram showing a solid-state battery having shock and vibration absorbing features including springs integrated therein, in accordance with an embodiment of the present invention;

FIG. 3 is a schematic cross-section diagram showing a solid-state battery having shock and vibration absorbing features including dampeners integrated therein, in accordance with an embodiment of the present invention;

FIG. 4 is a block/flow diagram showing a system for making a solid-state battery, in accordance with an embodiment of the present invention;

FIG. 5 is a schematic diagram showing a neural network for a predictive solid-state battery model, in accordance with an embodiment of the present invention;

FIG. 6 is a schematic diagram showing a neural network for a predictive solid-state battery model, in accordance with an embodiment of the present invention; and

FIG. 7 is a flow diagram showing methods for designing and fabricating a solid-state battery having shock and vibration absorbing features, in accordance with an embodiment of the present invention.

### DETAILED DESCRIPTION

In accordance with embodiments of the present invention, a battery design system is described that identifies and integrates appropriate shock absorbing measures within a solid-state battery and its components. A solid-state battery includes, as components, a cathode, an anode, solid-state electrolyte, an electrolyte/anode interface, an electrolyte/cathode interface and structural surroundings. In an embodiment, biasing/damping members and shock absorbing materials are employed within the solid-state battery to counteract natural shock and vibration forces as well as operational shock and vibration forces. Since cracks in a solid-state battery can lead to failure of the battery, the biasing members and shock absorbing materials are sized, positioned and integrated within and among the components of the solid-state battery to counter stress/strain within the solid-state battery. The stress/strain within the solid-state battery can otherwise lead to cracks and crack propagation. The biasing/damping members and shock absorbing materials can be three dimensionally (3D) printed and can include the same or similar materials as the components in which they are embedded.

In an embodiment, the battery design system analyzes operational parameters, solid-state electrodes, electrolyte materials, and potential vibrations or mechanical forces that may propagate through the battery. The system can execute, e.g., a digital twin simulation to identify an optimal integration of elastomeric interfaces. The system can analyze intended dimensions of the battery with optimized elastomeric interfaces to generate a 3D model. A 3D or 4D printing may be utilized to capture non-physical stress that may be applied to a battery to infuse robust structures.

Prior to solid-state battery printing, the system can analyze the operating environment, and how much vibration or potential stresses may propagate through a life of the solid-state battery. Potential levels of vibrational amplitude or mechanical stresses that may be transmitted to the solid-state battery can be determined, and a threshold of vibrational energy or shock that may be absorbed prior to potential electrolyte cracking can be accounted for using the digital twin simulations for the material properties of the solid-state battery.

Based on the vibration or shock propagation simulation through the solid-state battery, the system can identify what type of spring/damping effect should be integrated within the solid-state battery. Spring/dampener functionality can be applied on the electrodes and solid-state electrolyte so that the generated vibrations and mechanical stresses can be absorbed. Based on dimensions of the solid-state battery, material properties of the electrolyte and electrodes, and an estimated amount of propagated vibration through the solid-state battery, the system can identify countermeasure properties and appropriate integration positions. This can be performed using a 3D model and employing the twin simulation to arrive at an optimal solution. The solid-state battery can then be 3D printed from the generated 3D model.

In an embodiment, systems and methods are provided that infuse shock absorbing components into a 3D printed battery based on expected movement and wear and tear of the solid-state battery. The systems and methods can employ a 3D printer, slicing software, and other necessary software for 3D battery printing. The systems and methods can integrate with a generative adversarial network (GAN) to create a dynamic battery necessary for a space, size, and other physical requirements for the print of the solid-state battery. The systems and methods then derive the necessary use functionality needed for the solid-state battery by taking a 3D design file of the dynamically created solid-state battery and applying various forces and impulses to it to discover structural weakness based on its physical properties (e.g., shape size, design, etc.). Structural weakness can be determined by running through a life cycle of the solid-state battery under operational conditions or taking actions and activities of the expected device under a factor of safety (use a larger battery) and simulating a standard order of magnitude and type of movement.

Operational conditions can be determined by customer specifications or other methods. In an embodiment, operational conditions can be determined by employing an Internet of Things (IoT) device on a test battery or a battery employed in operational conditions. For example, a car battery can be equipped with shock and vibration sensors and data can be collected over the life cycle of the battery through IoT communication that remits information based on expected or real world usage of the given device or battery.

The 3D model of the solid-state battery can employ a threshold of space conversion for an amount of acceptable battery. In other words, a battery size is evaluated for stress to determine support transference, which is how the battery supports its weight and external forces for its size/output. This can be employed to compare a 3D printed solid-state battery's efficiency against the success of a traditional battery. The 3D print model can iteratively replace battery segments at derived weakness points with reinforcements. The reinforcement of these pieces may include but is not limited to springs, pressure outlets and other physical 3D printed components. Other protections for the solid-state battery against damaging elements can also be determined. For example, placement of mounting features, terminal couplings, coatings, etc.

The system can employ feedback to improve the solid-state battery by employing 3D model simulations as well as in-field use (with, e.g., feedback from IoT data sources) to gauge the efficiency of vibration reduction. The design of the solid-state battery can be improved with battery usage, and a new print format can be employed that validates the success in the re-printed solidi-state battery.

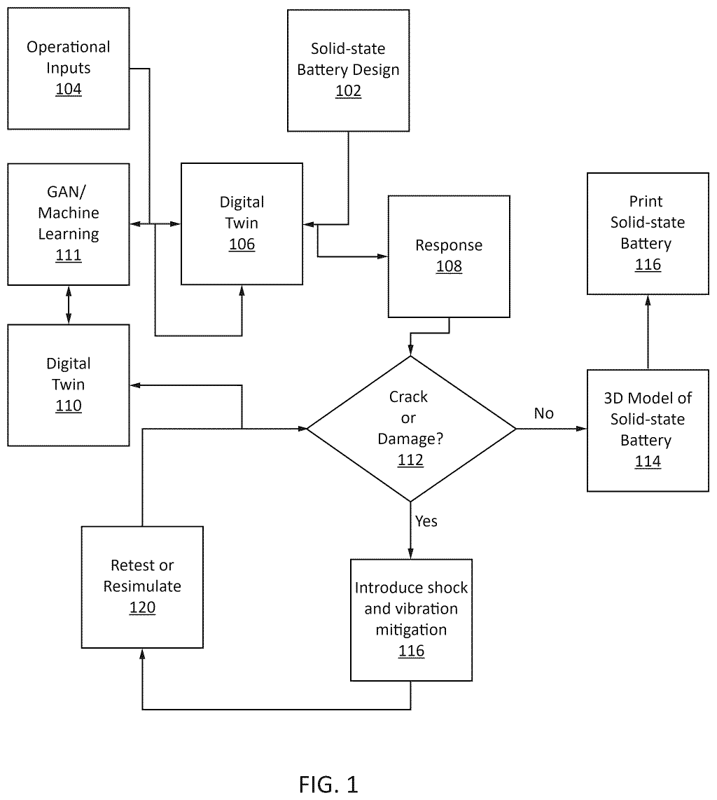

Referring now to the drawings in which like numerals represent the same or similar elements and initially to FIG. 1, a system 100 for designing solid-state batteries with mechanical force protection is shown in accordance with embodiments of the present invention. In an embodiment, the system 100 analyzes operational parameters, solid-state electrodes, electrolyte materials, and potential vibrations or mechanical forces that may propagate through the battery. The system 100 can execute, e.g., a digital twin simulation to identify an optimal integration of elastomeric interfaces. The system 100 employs the digital twin and a machine learning system that tracks the behavior of the solid-state battery in response to actions and determines what types and positions are needed for shock and vibration countermeasures associated with a particular response. The system 100 can analyze intended dimensions of the battery with optimized elastomeric interfaces to generate a 3D model. A 3D or 4D printing may be utilized to capture non-physical stress that may be applied to a battery to infuse robust structures.

An initial solid-state battery design 102 functions as a starting point to re-design a solid-state battery with mechanical protection. The initial solid-state battery design 102 can include a design concept or include an existing solid-state battery design. A digital twin 106 of the initial solid-state battery design 102 can be created.

A digital twin is a virtual representation of an object or system designed to reflect a physical object accurately. The digital twin 106 can be made to span the solid-state battery's lifecycle and can be updated with real-time data, use simulations and machine learning. The initial solid-state battery design 102 can be equipped with shock and vibration sensors. The sensors produce response data about different aspects of the performance of the initial solid-state battery design 102. The response data is applied to the digital twin 106, which is stored in memory. After being provided with the relevant data, the digital twin 106 can be utilized to conduct simulations and analyze performance to determine likely shock and vibrations responses that would occur in the solid-state battery design. A response 108 of the solid-state battery design 102 is quantified and characterized.

Once the shock and vibration response 108 is known, a new digital twin 110 could be created to identify areas or components within the solid-state battery where potential cracks or damage can occur under the response 108. The digital twin 110 reflects the geometry and materials of the solid-state battery design 102 to which the response 108 can be applied. By having better and constantly updated data related to a wide range of areas, combined with the added computing power that accompanies a virtual environment, digital twins can be employed to simulate more aspects of the solid-state design 102 to provide a more accurate response 108.

In block 112, a determination is made as to whether a crack or damage occurs due to the response 108. Geometry and materials of the solid-state battery design 102 are employed in the analysis to determine if and where cracks or damage can occur on the solid-state battery design 102 as a result of the response 108. Digital twins can employ computer-based solutions as well as data based solutions to assist in identifying and quantifying crack initiation, propagation and failure mode analysis.

If in block 112, a crack or damage results from the response 108, then shock and vibration mitigation is introduced in block 116. The shock and vibration mitigation or countermeasures can include dimension changes, stress relief structures, shock absorbing materials, springs (e.g., helical, leaf, etc.) or other components within the solid-state battery design 102. Using the digital twin 110, the locations of probable crack propagation can be determined.

Machine learning can be employed to associate a response profile of the response 108 to particular countermeasures and identify optimal positions for these countermeasures. In block 111, a machine learning model is trained to perform battery feature analysis to predict types, placement and magnitudes (sizes) or countermeasures within the solid-state battery capable of reducing shock and vibration responses to acceptable levels. Acceptable levels can be determined based on the useful life of the battery, its materials and its stress profiles, etc. For example, a long-short term memory (LSTM) neural network may be used to process sequences of shock and vibration responses to countermeasures to predict battery designs that would result in acceptable levels. The trained predictive model associates the shock and vibration responses to countermeasures. Training data can be collected from failure mode data from batteries and using IoT reported data or other data for data for solid-state batteries.

For example, the machine learning model in block 111 may select from a library of pre-generated responses that relate to different structural elements of a solid-state battery. In some cases, block 111 may use a generative adversarial network (GAN), trained on a set of existing responses and solid-state battery designs, to generate a new solid-state battery design.

The countermeasures could include a surface feature such as a divot or stress relief to counter possible crack probation. The shock and vibration mitigation results in types of countermeasures, magnitudes/sizing of the countermeasures and positions of different countermeasures depending on damage occurrences. These magnitudes and positions of different damage occurrences can be addressed by employing a number of different structures or remedies that can be incorporated into the digital twin 110.

The digital twin 110 is retested or re-simulated in block 120 with the mitigation features. After the retest or re-simulating in block 120, cracking or damage assessment is performed again in block 112. This process can continue until the design of the solid-state battery meets the requirements for shock and vibration.

When no crack or damage needs to be addressed, the digital twin 110 can be saved as a 3D or 4D model in block 114. The model in block 114 can be employed to print the solid-state battery using a 3D printer. The solid-state battery is printed with its solid-state components and any shock and vibration mitigating features. Although 3D printing is specifically contemplated, printing the new solid-state battery may include any appropriate type of manufacturing. Exemplary types of additive manufacturing that can be used include fuse deposition modeling (FDM), vat photopolymerization, and powder bed fusion.

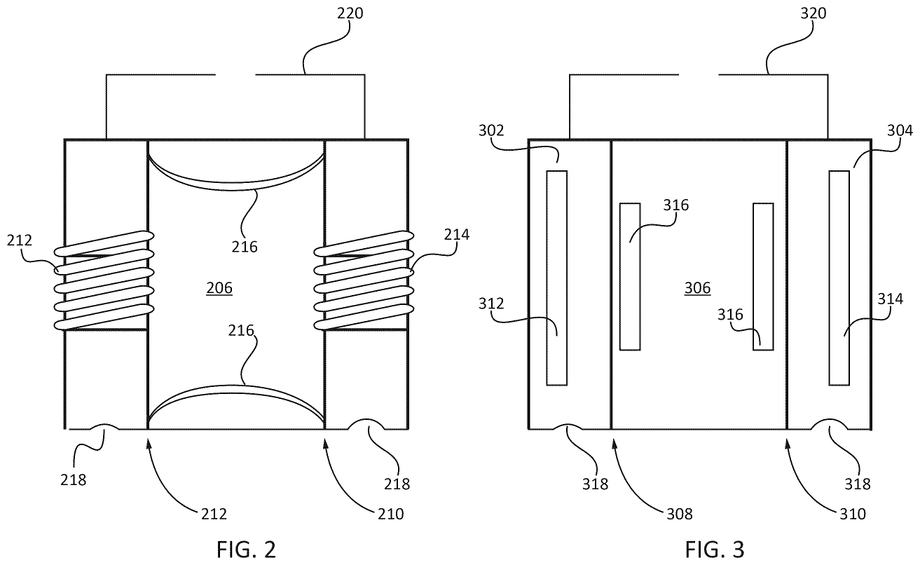

Referring to FIG. 2, a solid-state battery 200 includes a cathode 202, an anode 204, a solid-state electrolyte 206, an electrolyte/anode interface 210, an electrolyte/cathode interface 208 and structural surroundings 220 including terminals, mount structures and the like. In some embodiments, the cathode 202 (or positive electrode) can be made with the same compounds as a lithium-ion battery (e.g., lithium iron phosphate (LFP), lithium nickel manganese cobalt oxides (NMC), lithium ion manganese oxide (LMO), etc.). The solid-state electrolyte 206 can include a ceramic or solid polymer. The anode 204 can be made of lithium metal (pure lithium). Other materials and or combinations of these and other materials are also contemplated.

In an embodiment, shock and vibration mitigation features can include a number of forms. In example embodiments, the shock and vibration mitigation features can include helical springs 212, leaf springs 216, strain reliefs or divots 218. Other structures are also contemplated for shock and vibration mitigation features. For example, strain reliefs can be placed between different materials within the solid-state batter 200, the components can be separated into smaller parts and include shock and vibration mitigation features between the components, etc. The shock and vibration mitigation features are employed within the solid-state battery design 102 to counteract natural shock and vibration forces as well as operational shock and vibration forces.

Since cracks in a solid-state battery can lead to failure of the battery, the shock and vibration mitigation features are sized, positioned and integrated within and among the components of the solid-state battery 200 to counter stress/strain within the solid-state battery 200. The stress/strain within the solid-state battery 200 can otherwise lead to cracks and crack propagation. The shock and vibration mitigation features can be 3D or 4D printed along with the other components of the battery 200.

The shock and vibration mitigation features can include the same or similar materials as the components in which they are embedded. For example, the helical spring 212 can include a same material as the cathode 202. In an embodiment, the helical spring 212 can connect portions of the cathode 202 on opposite sides of the helical spring 212. The helical spring 214 can connect portions of the anode 204 on opposite sides of the helical spring 214. The helical springs 212, 214 can be biased or pretensioned to counteract stresses that could otherwise form cracks or cause damage. The bias or pretension can be fabricated into the battery 200 using particular materials and 3D printing techniques. For example, different materials can be employed or the same materials can be employed with a different density or other physical property difference that can be obtained by 3D printing. In another embodiment, the bias or pretension can be developed during the operation of the battery 200, e.g., relying on elevated operational temperatures and thermal expansion mismatches between materials. In this way, a pre-stress can be employed within the structure of the solid-state battery 200.

The shock and vibration mitigation features can include leaf springs 216 or other biasing members that can be embedded within the solid-state electrolyte 206. The leaf springs 216 can be biased or pretensioned to counteract stresses that could otherwise form cracks or cause damage. The bias or pretension can be fabricated into the battery 200 using particular materials and 3D printing techniques. For example, different materials can be employed or the same materials can be employed with a different density or other physical property difference that can be obtained by 3D printing. In another embodiment, the bias or pretension can be developed during the operation of the battery 200, e.g., relying on elevated operational temperatures and thermal expansion mismatches between materials. In this way, a pre-stress can be employed within the structure of the solid-state battery 200.

In some embodiments, the helical springs 212, 214 and the leaf springs 216 can be secured or include reliefs or voids around the helical springs 212, 214 and the leaf springs 216 or portions thereof to permit vibrational motion. It should be understood that the type of element and its placement for the shock and vibration mitigation features is not limited to the configuration shown in FIG. 2. Instead, any element can be placed at any location within the solid-state battery 200 since the solid-state battery 200 can be 3D printed.

In some embodiments, a surface area or areas, where dendrite formation and/or crack propagation has a higher likelihood of occurring, can include divots 218 or other contours to reduce stress at these locations. These contours can be included in the 3D printing of the solid-state battery 200.

Referring to FIG. 3, in another embodiment, a solid-state battery 300 includes a cathode 302, an anode 304, a solid-state electrolyte 306, an electrolyte/anode interface 310, an electrolyte/cathode interface 308 and structural surroundings 320 including terminals, mount structures and the like. The materials of solid-state battery 300 can include similar materials as described for solid-state battery 200. In an embodiment, shock and vibration mitigation features can include a number of forms. In example embodiments, the shock and vibration mitigation features can include elastomeric regions 312, 314 and 316, and strain reliefs or divots 318. Other structures are also contemplated for shock and vibration mitigation features. For example, strain reliefs can be placed between different materials within the solid-state battery 300, the components can be separated into smaller parts and include shock and vibration mitigation features between the components, etc. The shock and vibration mitigation features are employed within the solid-state battery 300 to counteract natural shock and vibration forces as well as operational shock and vibration forces.

Since cracks in a solid-state battery can lead to failure of the battery, the shock and vibration mitigation features are sized, positioned and integrated within and among the components of the solid-state battery 300 to counter stress/strain within the solid-state battery 300. The stress/strain within the solid-state battery 300 can otherwise lead to cracks and crack propagation. The shock and vibration mitigation features can be 3D or 4D printed along with the other components of the battery 300.

The shock and vibration mitigation features can include the same or similar materials as the components in which they are embedded. For example, the elastomeric regions 312, 314 and 316 can include a same material as the cathode 302, the anode 304 and the solid-state electrolyte 306, respectively. In an embodiment, the elastomeric regions 312, 314 and 316 can include a different porosity than surrounding materials. In this way a dampening effect is provided as mechanical waves travers the materials having different porosities. In other embodiments, different materials can be employed for the elastomeric regions 312, 314 and 316 so that Young's modulus is different between the materials to provide dampening of shock and vibration in the solid-state battery 300. The elastomeric regions 312, 314 and 316 can be biased or pretensioned to counteract stresses that could otherwise form cracks or cause damage. The bias or pretension can be fabricated into the battery 300 using particular materials and 3D printing techniques. In another embodiment, the bias or pretension can be developed during the operation of the battery 300, e.g., relying on elevated operational temperatures and thermal expansion mismatches between materials. In this way, a pre-stress can be employed within the structure of the solid-state battery 300.

In some embodiments, the elastomeric regions 312, 314 and 316 can be secured or include reliefs or voids around elastomeric regions 312, 314 and 316 or portions thereof. It should be understood that the type of element and its placement for the shock and vibration mitigation features is not limited to the configurations shown in FIGS. 2 and 3. Instead, any element and combinations thereof can be placed at any location within the solid-state battery 300 since the solid-state battery 300 can be 3D printed.

In some embodiments, a surface area or areas, where dendrite formation and/or crack propagation has a higher likelihood of occurring, can include divots 318 or other contours to reduce stress at these locations. These contours can be included in the 3D printing of the solid-state battery 300.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

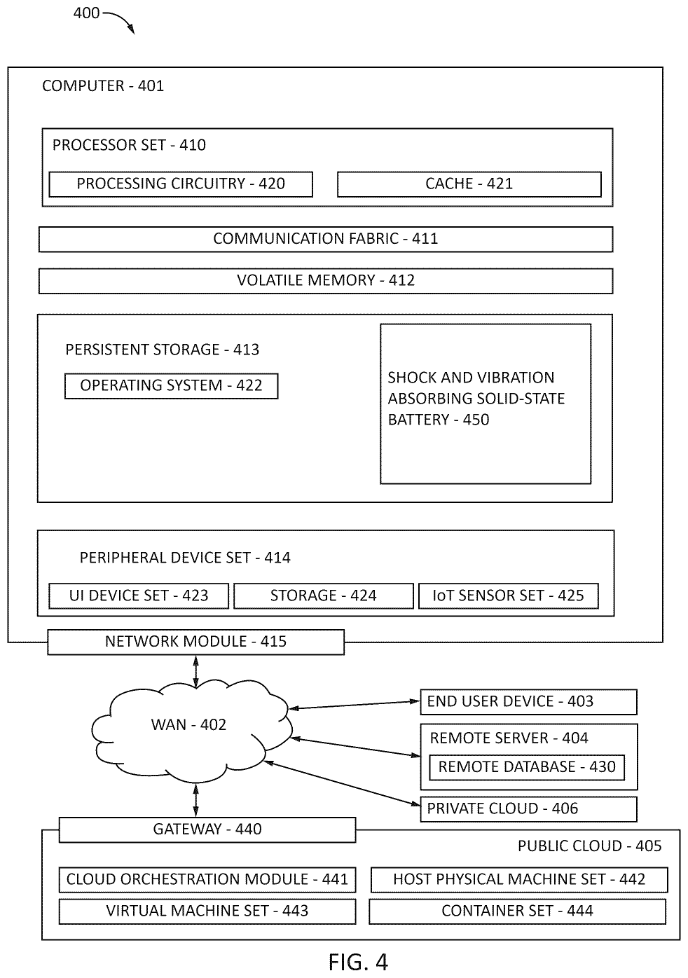

Referring to FIG. 4, a computing environment 400 contains an example of an environment for the execution of at least some of the computer code involved in performing the inventive methods, such as shock and vibration absorbing solid-state battery design 450. In addition to block 450, computing environment 400 includes, for example, computer 401, wide area network (WAN) 402, end user device (EUD) 403, remote server 404, public cloud 405, and private cloud 406. In this embodiment, computer 401 includes processor set 410 (including processing circuitry 420 and cache 421), communication fabric 411, volatile memory 412, persistent storage 413 (including operating system 422 and block 450, as identified above), peripheral device set 414 (including user interface (UI) device set 423, storage 424, and Internet of Things (IoT) sensor set 425), and network module 415. Remote server 404 includes remote database 430. Public cloud 405 includes gateway 440, cloud orchestration module 441, host physical machine set 442, virtual machine set 443, and container set 444.

COMPUTER 401 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 430. As is well understood in the art of computer technology, and depending upon the technology, performance of a computer-implemented method may be distributed among multiple computers and/or between multiple locations. On the other hand, in this presentation of computing environment 400, detailed discussion is focused on a single computer, specifically computer 401, to keep the presentation as simple as possible. Computer 401 may be located in a cloud, even though it is not shown in a cloud in FIG. 4. On the other hand, computer 401 is not required to be in a cloud except to any extent as may be affirmatively indicated.

PROCESSOR SET 410 includes one, or more, computer processors of any type now known or to be developed in the future. Processing circuitry 420 may be distributed over multiple packages, for example, multiple, coordinated integrated circuit chips. Processing circuitry 420 may implement multiple processor threads and/or multiple processor cores. Cache 421 is memory that is located in the processor chip package(s) and is typically used for data or code that should be available for rapid access by the threads or cores running on processor set 410. Cache memories are typically organized into multiple levels depending upon relative proximity to the processing circuitry. Alternatively, some, or all, of the cache for the processor set may be located “off chip.” In some computing environments, processor set 410 may be designed for working with qubits and performing quantum computing.

Computer readable program instructions are typically loaded onto computer 401 to cause a series of operational steps to be performed by processor set 410 of computer 401 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 421 and the other storage media discussed below. The program instructions, and associated data, are accessed by processor set 410 to control and direct performance of the inventive methods. In computing environment 400, at least some of the instructions for performing the inventive methods may be stored in block 450 in persistent storage 413.

COMMUNICATION FABRIC 411 is the signal conduction path that allows the various components of computer 401 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 412 is any type of volatile memory now known or to be developed in the future. Examples include dynamic type random access memory (RAM) or static type RAM. Typically, volatile memory 412 is characterized by random access, but this is not required unless affirmatively indicated. In computer 401, the volatile memory 412 is located in a single package and is internal to computer 401, but, alternatively or additionally, the volatile memory may be distributed over multiple packages and/or located externally with respect to computer 401.

PERSISTENT STORAGE 413 is any form of non-volatile storage for computers that is now known or to be developed in the future. The non-volatility of this storage means that the stored data is maintained regardless of whether power is being supplied to computer 401 and/or directly to persistent storage 413. Persistent storage 413 may be a read only memory (ROM), but typically at least a portion of the persistent storage allows writing of data, deletion of data and re-writing of data. Some familiar forms of persistent storage include magnetic disks and solid state storage devices. Operating system 422 may take several forms, such as various known proprietary operating systems or open source Portable Operating System Interface-type operating systems that employ a kernel. The code included in block 450 typically includes at least some of the computer code involved in performing the inventive methods.

PERIPHERAL DEVICE SET 414 includes the set of peripheral devices of computer 401. Data communication connections between the peripheral devices and the other components of computer 401 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 423 may include components such as a display screen, speaker, microphone, wearable devices (such as goggles and smart watches), keyboard, mouse, printer, touchpad, game controllers, and haptic devices. Storage 424 is external storage, such as an external hard drive, or insertable storage, such as an SD card. Storage 424 may be persistent and/or volatile. In some embodiments, storage 424 may take the form of a quantum computing storage device for storing data in the form of qubits. In embodiments where computer 401 is required to have a large amount of storage (for example, where computer 401 locally stores and manages a large database) then this storage may be provided by peripheral storage devices designed for storing very large amounts of data, such as a storage area network (SAN) that is shared by multiple, geographically distributed computers. IoT sensor set 425 is made up of sensors that can be used in Internet of Things applications. For example, one sensor may be a thermometer and another sensor may be a motion detector.

NETWORK MODULE 415 is the collection of computer software, hardware, and firmware that allows computer 601 to communicate with other computers through WAN 402. Network module 415 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 415 are performed on the same physical hardware device. In other embodiments (for example, embodiments that utilize software-defined networking (SDN)), the control functions and the forwarding functions of network module 415 are performed on physically separate devices, such that the control functions manage several different network hardware devices. Computer readable program instructions for performing the inventive methods can typically be downloaded to computer 401 from an external computer or external storage device through a network adapter card or network interface included in network module 415. WAN 402 is any wide area network (for example, the internet) capable of communicating computer data over non-local distances by any technology for communicating computer data, now known or to be developed in the future. In some embodiments, the WAN 402 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 403 is any computer system that is used and controlled by an end user (for example, a customer of an enterprise that operates computer 401), and may take any of the forms discussed above in connection with computer 401. EUD 403 typically receives helpful and useful data from the operations of computer 401. For example, in a hypothetical case where computer 401 is designed to provide a recommendation to an end user, this recommendation would typically be communicated from network module 415 of computer 401 through WAN 402 to EUD 403. In this way, EUD 403 can display, or otherwise present, the recommendation to an end user. In some embodiments, EUD 403 may be a client device, such as thin client, heavy client, mainframe computer, desktop computer and so on.

REMOTE SERVER 404 is any computer system that serves at least some data and/or functionality to computer 401. Remote server 404 may be controlled and used by the same entity that operates computer 401. Remote server 404 represents the machine(s) that collect and store helpful and useful data for use by other computers, such as computer 401. For example, in a hypothetical case where computer 401 is designed and programmed to provide a recommendation based on historical data, then this historical data may be provided to computer 401 from remote database 430 of remote server 404.

PUBLIC CLOUD 405 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 405 is performed by the computer hardware and/or software of cloud orchestration module 441. The computing resources provided by public cloud 405 are typically implemented by virtual computing environments that run on various computers making up the computers of host physical machine set 442, which is the universe of physical computers in and/or available to public cloud 405. The virtual computing environments (VCEs) typically take the form of virtual machines from virtual machine set 443 and/or containers from container set 444. It is understood that these VCEs may be stored as images and may be transferred among and between the various physical machine hosts, either as images or after instantiation of the VCE. Cloud orchestration module 441 manages the transfer and storage of images, deploys new instantiations of VCEs and manages active instantiations of VCE deployments. Gateway 440 is the collection of computer software, hardware, and firmware that allows public cloud 405 to communicate through WAN 402. Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 406 is similar to public cloud 405, except that the computing resources are only available for use by a single enterprise. While private cloud 406 is depicted as being in communication with WAN 402, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 405 and private cloud 406 are both part of a larger hybrid cloud.

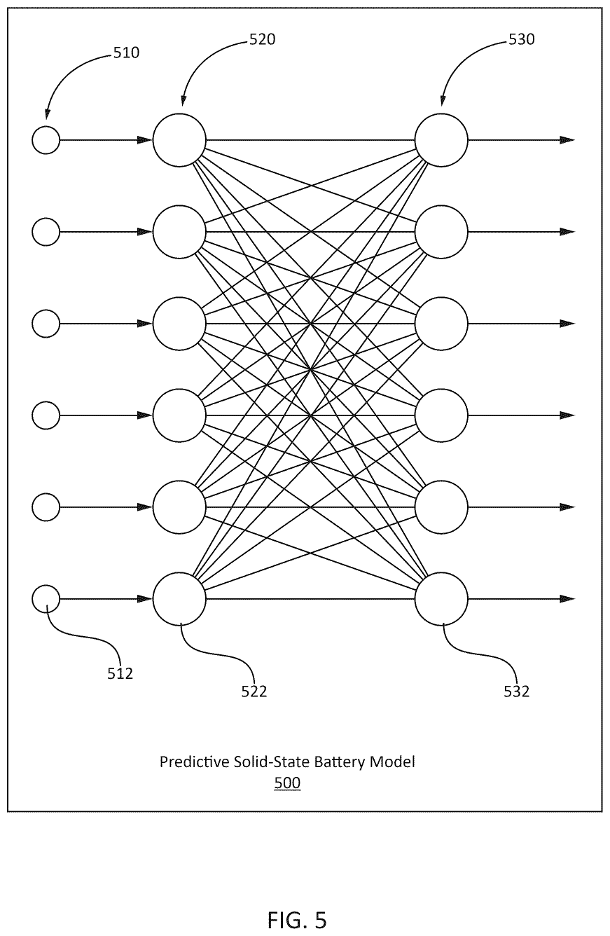

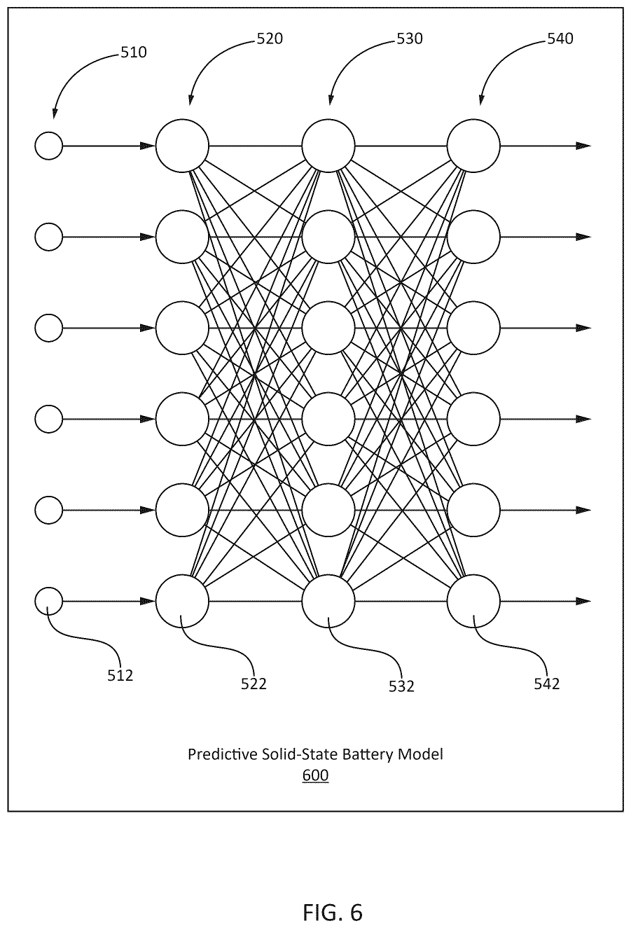

Referring to FIGS. 5 and 6, exemplary neural network architectures are shown, which may be used to implement parts of the present models, such as predictive solid-state battery model 500/600. A neural network is a generalized system that improves its functioning and accuracy through exposure to additional empirical data. The neural network becomes trained by exposure to the empirical data. During training, the neural network stores and adjusts a plurality of weights that are applied to the incoming empirical data. By applying the adjusted weights to the data, the data can be identified as belonging to a particular predefined class from a set of classes or a probability that the input data belongs to each of the classes can be output.

The empirical data, also known as training data, from a set of examples can be formatted as a string of values and fed into the input of the neural network. Each example may be associated with a known result or output. Examples can include solid-state batteries having particular failure modes being associated with countermeasures, shock and vibration response features associated with countermeasures, etc. Each example can be represented as a pair, (x, y), where x represents the input data and y represents the known output. The input data may include a variety of different data types, and may include multiple distinct values. The network can have one input node for each value making up the example's input data, and a separate weight can be applied to each input value. The input data can, for example, be formatted as a vector, an array, or a string depending on the architecture of the neural network being constructed and trained.

The neural network “learns” by comparing the neural network output generated from the input data to the known values of the examples, and adjusting the stored weights to minimize the differences between the output values and the known values. The adjustments may be made to the stored weights through back propagation, where the effect of the weights on the output values may be determined by calculating the mathematical gradient and adjusting the weights in a manner that shifts the output towards a minimum difference. This optimization, referred to as a gradient descent approach, is a non-limiting example of how training may be performed. A subset of examples with known values that were not used for training can be used to test and validate the accuracy of the neural network.

During operation, the trained neural network can be used on new data that was not previously used in training or validation through generalization. The adjusted weights of the neural network can be applied to the new data, where the weights estimate a function developed from the training examples. The parameters of the estimated function which are captured by the weights are based on statistical inference.

In layered neural networks, nodes are arranged in the form of layers. An exemplary simple neural network has an input layer 520 of source nodes 522, and a single computation layer 530 having one or more computation nodes 532 that also act as output nodes, where there is a single computation node 532 for each possible category into which the input example could be classified. An input layer 520 can have a number of source nodes 522 equal to the number of data values 512 in the input data 510. The data values 512 in the input data 510 can be represented as a column vector. Each computation node 532 in the computation layer 530 generates a linear combination of weighted values from the input data 510 fed into nodes of the input layer 520, and applies a non-linear activation function that is differentiable to the sum. The exemplary simple neural network can perform classification on linearly separable examples (e.g., patterns).

A deep neural network, such as a multilayer perceptron, can have an input layer 520 of source nodes 522, one or more computation layer(s) 530 having one or more computation nodes 532, and an output layer 540, where there is a single output node 542 for each possible category into which the input example could be classified. An input layer 520 can have a number of source nodes 522 equal to the number of data values 512 in the input data 510. The computation nodes 532 in the computation layer(s) 530 can also be referred to as hidden layers, because they are between the source nodes 522 and output node(s) 542 and are not directly observed. Each node 532, 542 in a computation layer generates a linear combination of weighted values from the values output from the nodes in a previous layer, and applies a non-linear activation function that is differentiable over the range of the linear combination. The weights applied to the value from each previous node can be denoted, for example, by w₁, w₂, . . . w_{n-1,} wₙ. The output layer provides the overall response of the network to the input data. A deep neural network can be fully connected, where each node in a computational layer is connected to all other nodes in the previous layer, or may have other configurations of connections between layers. If links between nodes are missing, the network is referred to as partially connected.

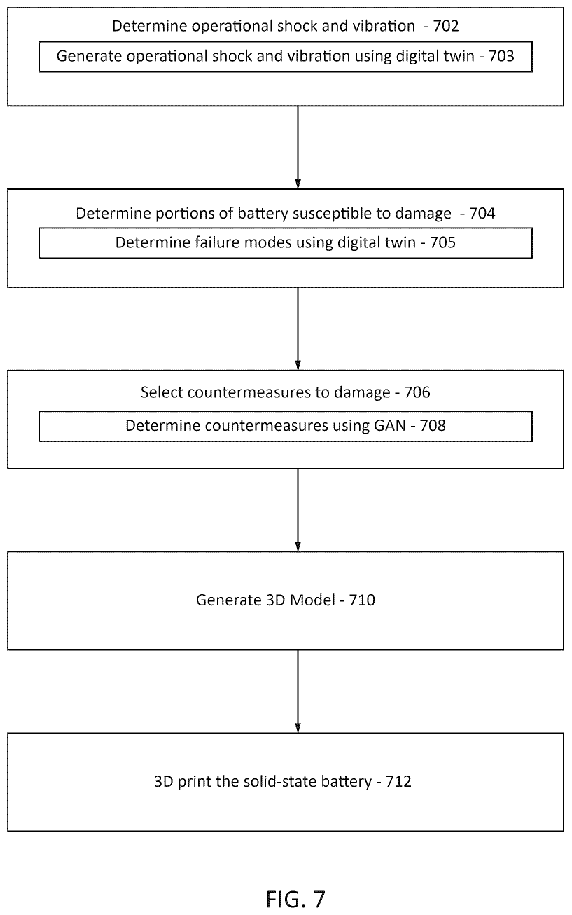

Referring to FIG. 7, a system/computer-implemented method for battery design includes infusing shock and vibration absorbing components into a 3D printed battery based on expected movement and wear and tear of the solid-state battery. The systems and methods can employ a 3D printer, slicing software, and other necessary software for 3D battery printing. In block 702, operational shock and vibration imparted to a solid-state battery are determined. This can include employing a generative adversarial network (machine learning) to create a dynamic battery to test a design under simulated conditions for a shape, size, and other physical requirements of a solid-state battery design. The dynamic battery can include a digital twin of a solid-state battery, and the digital twin can be employed to determine the operational shock and vibration, in block 703.

The system can analyze an operating environment, and how much shock, vibration and/or potential stresses may propagate through a life of the solid-state battery. Potential levels of vibrational amplitude or mechanical stresses that may be transmitted to the solid-state battery can be determined, and a threshold of vibrational energy or shock that may be absorbed prior to potential electrolyte cracking can be accounted for using, e.g., digital twin simulations with the material properties of the solid-state battery.

In block 704, a determination is made as to which portions of the solid-state battery are susceptible to damage. The system can derive the necessary use functionality needed for the solid-state battery by taking a 3D design file of the dynamically created solid-state battery and applying various forces and impulses, determined in block 702, to it to discover structural weakness based on its physical properties (e.g., shape size, design, etc.). Structural weakness can be determined by running through a life cycle of the solid-state battery under operational conditions or taking actions and activities of the expected device under a factor of safety (use a larger battery) and simulating a standard order of magnitude and type of movement. In block 705, a digital twin of a solid-state battery can be generated and the operational shock and vibration can be applied to the digital twin to determine failure modes.

In block 706, countermeasures are selected for the portions of the solid-state battery that are susceptible to damage by identifying shock and vibration elements and positions for the shock and vibration elements in the solid-state battery. The countermeasures can include embedded springs, dampers, an elastic region embedded in a component of the solid-state battery having a different elasticity than the component, divots, contours, etc.

Based on the vibration or shock propagation simulation through the solid-state battery, the system can identify what type of spring/damping effect should be integrated within the solid-state battery. Spring/damping functionality can be applied on the components of the solid-state battery (e.g., cathode, anode and solid-state electrolyte) so that the generated vibrations and mechanical stresses can be absorbed. Based on dimensions of the solid-state battery, material properties of the electrolyte and electrodes, and an estimated amount of propagated vibration/shock through the solid-state battery, the system can identify spring/damper properties and appropriate integration positions. This can be performed using a 3D model, machine learning and the twin simulation to arrive at an optimal solution.

In block 708, a generative adversarial network (GAN) trained on damaged solid-state batteries can be employed to identify what type of spring/damping effect should be integrated.

In block 710, a 3D design for a new solid-state battery including the countermeasures is generated. In block 712, the new solid-state battery is fabricated according to the 3D design using an additive manufacturing process, e.g., a 3D or 4D printing method.

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor-or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), FPGAs, and/or PLAs.

These and other variations of a hardware processor subsystem are also contemplated in accordance with embodiments of the present invention.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments of interface modulation and button function replication (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A computer-implemented method for battery design, comprising:
determining operational shock and vibration imparted to a solid-state battery;
determining portions of the solid-state battery susceptible to damage;
selecting countermeasures for the portions by identifying shock and vibration elements and positions for the shock and vibration elements in the solid-state battery;
generating a three-dimensional (3D) design for a new solid-state battery including the countermeasures; and
fabricating the new solid-state battery according to the 3D design using an additive manufacturing process.

2. The method of claim 1, wherein the countermeasures include an embedded spring.

3. The method of claim 1, wherein the countermeasures include an elastic region embedded in a component of the solid-state battery having a different elasticity than the component.

4. The method of claim 1, wherein selecting countermeasures includes using a generative adversarial network trained on damaged solid-state batteries.

5. The method of claim 1, wherein determining the portions of the solid-state battery susceptible to damage includes generating a digital twin of a solid-state battery and applying the operational shock and vibration to the digital twin to determine failure modes.

6. The method of claim 1, wherein determining the operational shock and vibration imparted to the solid-state battery includes generating a digital twin of a solid-state battery and generating a response to the operational shock and vibration on the digital twin.

7. A system for battery design, comprising:
a hardware processor; and
a memory that stores a computer program which, when executed by the hardware processor, causes the hardware processor to:
determine operational shock and vibration imparted to a solid-state battery;
determine portions of the solid-state battery susceptible to damage;
select countermeasures for the portions by identifying shock and vibration elements and positions for the shock and vibration elements in the solid-state battery;
generate a three-dimensional (3D) design for a new solid-state battery including the countermeasures; and
fabricate the new solid-state battery according to the 3D design using an additive manufacturing process.

8. The system of claim 7, wherein the countermeasures include incorporating an embedded spring in the new solid-state battery.

9. The system of claim 7, wherein the countermeasures include incorporating an elastic region in a component of the solid-state battery.

10. The system of claim 7, further comprising a generative adversarial network trained on damaged solid-state batteries to select the countermeasures.

11. The system of claim 7, further comprising a digital twin of a solid-state battery, the digital twin to simulate application of the operational shock and vibration to the solid-state battery to determine failure modes.

12. The system of claim 7, further comprising a digital twin of a solid-state battery to determine a shock and vibration response on the solid-state battery.

13. A solid-state battery, comprising:
components including:
an anode;
a cathode; and
a solid-state electrolyte disposed between the anode and the cathode; and
a countermeasure integrally incorporated within at least one of the components to absorb mechanical energy to prevent physical damage to the components.

14. The battery of claim 13, wherein the countermeasure includes an embedded spring within at least one of the components.

15. The battery of claim 14, wherein the embedded spring includes a helical spring.

16. The battery of claim 14, wherein the embedded spring includes a leaf spring.

17. The battery of claim 13, wherein the countermeasure includes an elastic region embedded within at least one of the components.

18. The battery of claim 17, wherein the elastic region is embedded within at least one of the components and includes a different elasticity than a component in which the elastic region is embedded.

19. The battery of claim 17, wherein the elastic region is embedded within at least one of the components and includes a different porosity than a component in which the elastic region is embedded.

20. The battery of claim 13, wherein the solid-state battery is printed in an additive manufacturing process.
